(19) United States
(12) Patent Application Publication
(10) Pub. No.: US 2024/0283198 A1
(43) Pub. Date: Aug. 22, 2024

(54) Electrical Connector

(71) Applicants: Tyco Electronics Holdings (Bermuda) No. 7 Limited, Hamilton (BM); Tyco Electronics (Shanghai) Co., Ltd., Shanghai (CN)

(72) Inventors: Hengkang Wu, Dongguan (CN); Xinjie (David) Zhang, Shanghai (CN); Ching Hsiang Chang, Taipei (TW); Zhaohai (Tim) Xue, Shanghai (CN)

(73) Assignees: Tyco Electronics Holdings (Bermuda) No. 7 Limited, Hamilton (BM); Tyco Electronics (Shanghai) Co., Ltd., Shanghai (CN)

(21) Appl. No.: 18/581,817

(22) Filed: Feb. 20, 2024

(30) Foreign Application Priority Data
Feb. 20, 2023 (CN) 202310143692.4

(51) Int. Cl. H01R 13/6587; H01R 12/72; H01R 13/6471

(52) U.S. Cl. CPC H01R 13/6587; H01R 12/722; H01R 13/6471

(57) ABSTRACT

An electrical connector includes a housing, first and second rows of terminals arranged in the housing, and a ground shield assembly. The first and second rows of terminals are separated from each other and adapted to electrically connect with corresponding terminals of a mated electrical connector. The first and second rows of terminals each include a ground terminal connected to a ground layer of a circuit board and a signal terminal connected to a signal lead wire of the circuit board. The ground shield assembly is positioned between the signal terminal of the first row of terminals and the signal terminal of the second row of terminals and is electrically connected to the ground layer. The ground shield assembly is in electrical contact with a corresponding ground terminal at at least one position of each of at least one ground terminal of the first and/or second row of terminals.

### CROSS-REFERENCE TO RELATED APPLICATION

This application claims priority from Chinese Patent Application No. CN 202310143692.4 filed on Feb. 20, 2023, the contents of which in its entirety are herein incorporated by reference.

### FIELD OF THE INVENTION

The present disclosure relates to electrical connectors.

### BACKGROUND

Current electrical connectors adapted to be mated with card-type electrical connectors suffer from severe signal interference, particularly severe near-end crosstalk between signal terminals of two rows of terminals of the electrical connectors. Further, these connectors experience additional undesired characteristics, such as high-frequency resonance, cross talk, and return loss, resulting in poor signal integrity. Therefore, it is desired to provide an electrical connector that reduces signal interference and improves the signal integrity, particularly an electrical connector that improves high-frequency resonance.

### SUMMARY

An electrical connector according to an embodiment of the present disclosure is adapted to be installed on a circuit board and to be connected with a mated electrical connector. The connector includes a housing, a first row of terminals and a second row of terminals arranged in the housing, and a ground shield assembly. The first and second rows of terminals are separated from each other and are adapted to be electrically connected with corresponding terminals of the mated electrical connector. The first row of terminals and the second row of terminals each comprise a ground terminal adapted to be connected to a ground layer of the circuit board, and a signal terminal adapted to be connected to a signal lead wire of the circuit board. The ground shield assembly is at least partially positioned between the signal terminal of the first row of terminals and the signal terminal of the second row of terminals and is adapted to be electrically connected to the ground layer. The ground shield assembly is in electrical contact with a corresponding ground terminal at at least one position of each of at least one ground terminal of the first row of terminals and/or the second row of terminals.

### BRIEF DESCRIPTION OF THE DRAWINGS

The invention will now be described by way of example with reference to the accompanying Figures, of which:

FIG. 1 is a perspective view of an electrical connector, a mated electrical connector, and a circuit board according to the present disclosure.

FIG. 2 is a perspective view of an electrical connector, a mated electrical connector, and a circuit board, which are connected together, according to the present disclosure.

FIG. 3 is an exploded view of an electrical connector according to an embodiment of the present disclosure.

FIG. 4 is a perspective view of a first row of terminals of the electrical connector assembled together with a common ground member.

FIG. 5 is a perspective view of a second row of terminals of the electrical connector assembled together with a common ground member.

FIG. 6 is a perspective view of the electrical connector with a housing removed.

FIG. 7 is a sectional view of the electrical connector.

FIG. 8 is an exploded view of an electrical connector according to another embodiment of the present disclosure.

FIG. 9 is a perspective view of a second row of terminals of the electrical connector assembled together with a common ground member.

FIG. 10 is a sectional view of the electrical connector.

FIG. 11 is an exploded view of an electrical connector according to another embodiment of the present disclosure.

FIG. 12 is a perspective view of a conductive shield member with a positioning member of the electrical connector.

FIG. 13 is a sectional view of the electrical connector.

FIG. 14 is an exploded view of an electrical connector according to another embodiment of the present disclosure.

FIG. 15 is a perspective view of a second row of terminals of the electrical connector assembled together with a common ground member.

FIG. 16 is a perspective view of a third common ground member of the electrical connector.

FIG. 17 is a sectional view of the electrical connector.

FIG. 18 is an exploded view of an electrical connector according to an embodiment of the present disclosure.

FIG. 19 is a perspective view of a conductive shield member with a positioning member of the electrical connector.

FIG. 20 is a perspective view of the conductive shield member of the electrical connector.

FIG. 21 is a sectional view of the electrical connector.

FIG. 22 is an exploded view of an electrical connector according to another embodiment of the present disclosure.

FIG. 23 is a perspective view of the electrical connector after assembling.

FIG. 24 is a perspective view of a common ground member of the electrical connector.

FIG. 25 is a sectional view of the electrical connector.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Embodiments of the present disclosure include electrical connectors adapted to be installed on a circuit board and connected with a mated electrical connector. The electrical connector includes a housing, a first row of terminals and a second row of terminals arranged in the housing, and a ground shield assembly. The first row of terminals and the second row of terminals are separated from each other and adapted to be electrically connected with corresponding terminals of the mated electrical connector. The first row of terminals and the second row of terminals each include a ground terminal adapted to be connected to a ground layer of the circuit board and a signal terminal adapted to be connected to a signal lead wire of the circuit board. The ground shield assembly is at least partially positioned between the signal terminal of the first row of terminals and the signal terminal of the second row of terminals and is configured to be electrically connected to the ground layer. The ground shield assembly is adapted to be in electrical contact with a corresponding ground terminal at at least one position of each of at least one ground terminal of the first row of terminals and/or the second row of terminals.

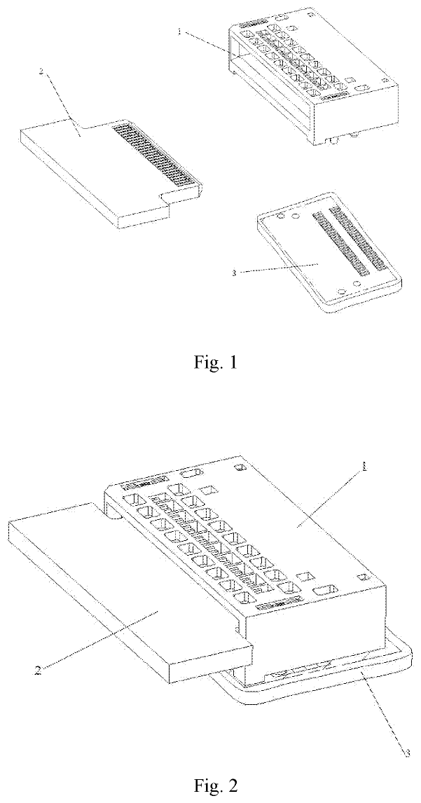

FIG. 1 is a perspective view of an electrical connector, a mated electrical connector, and a circuit board according to the present disclosure. FIG. 2 is a perspective view of an electrical connector, a mated electrical connector, and a circuit board, which are connected together, according to the present disclosure.

An electrical connector 1 according to the present disclosure is adapted to be installed on a circuit board 3. A signal terminal of the electrical connector can be connected to a signal lead wire of the circuit board 3, and a ground terminal of the electrical connector can be connected to a ground layer or a ground wire of the circuit board 3. The electrical connector 1 further has an inserting end, by which the electrical connector can be electrically connected with a mated electrical connector 2 such as a card-type electrical connector. The signal terminal and the ground terminal of the electrical connector 1 can be electrically connected to a corresponding signal terminal and a corresponding ground terminal of the mated electrical connector 2, respectively, so that the mated electrical connector 2 is connected to the circuit board 3 via the electrical connector 1.

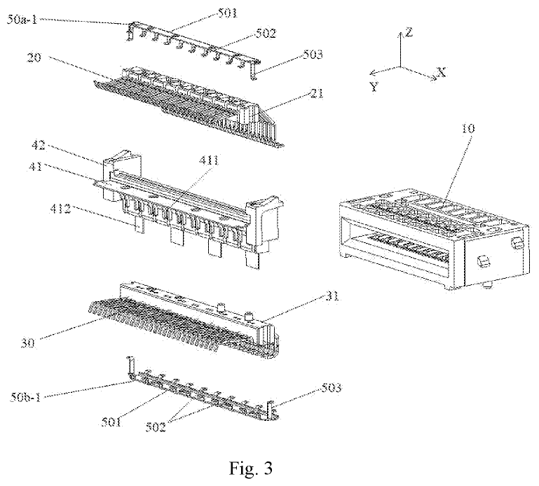

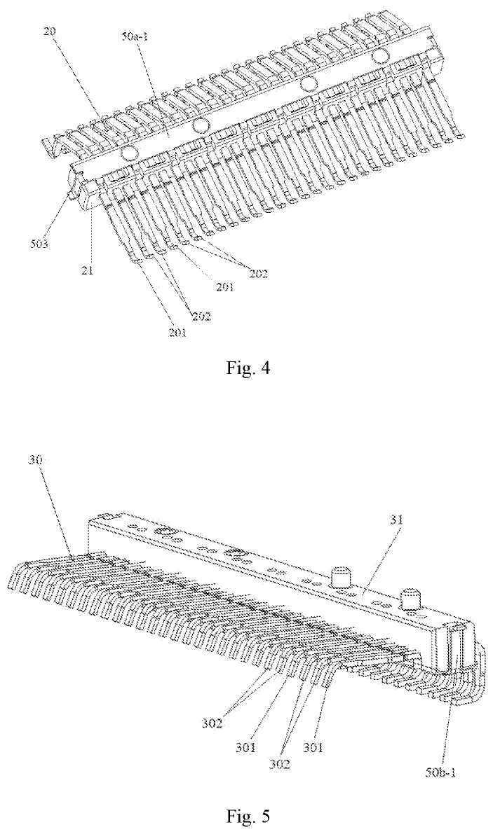

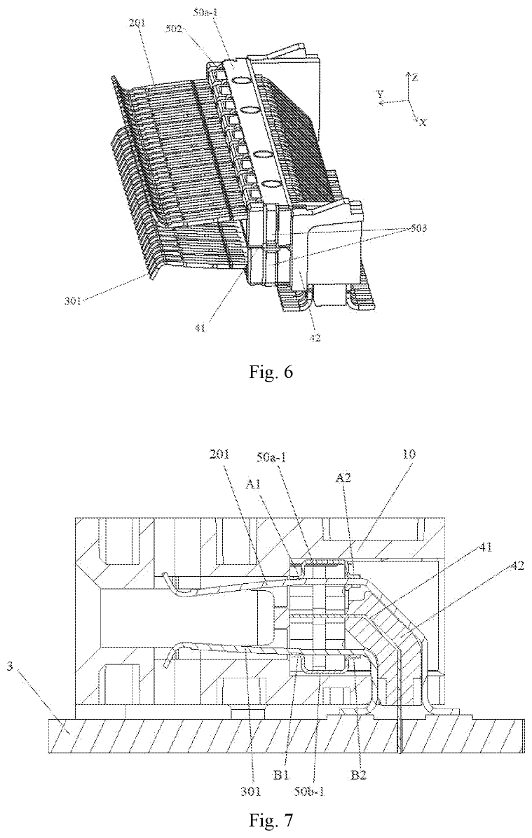

FIG. 3 is an exploded view of an electrical connector according to an embodiment of the present disclosure. FIG. 4 is a perspective view of a first row of terminals of the electrical connector assembled together with a common ground member. FIG. 5 is a perspective view of a second row of terminals of the electrical connector assembled together with a common ground member. FIG. 6 is a perspective view of the electrical connector with a housing removed. FIG. 7 is a sectional view of the electrical connector. FIGS. 3 to 7 will be discussed together.

The electrical connector includes a housing 10, a first row of terminals 20, and a second row of terminals 30. The first row of terminals 20 and the second row of terminals 30 are housed in the housing 10 such that they are separated from each other, and are adapted to be electrically connected with corresponding terminals of the mated electrical connector 2. The first row of terminals 20 includes a first ground terminal 201 adapted to be connected to a ground layer of the circuit board 3 and a first signal terminal 202 adapted to be connected to a signal lead wire of the circuit board 3. The second row of terminals 30 includes a second ground terminal 301 adapted to be connected to a ground layer of the circuit board 3 and a second signal terminal 302 adapted to be connected to a signal lead wire of the circuit board 3.

In the illustrated embodiment, the first row of terminals 20 includes the first ground terminal 201 arranged between the signal terminals 202. In other words, the first ground terminal 201 and the first signal terminal 202 of the first row of terminals 20 are arranged alternately with each other. As better shown in FIGS. 4 and 6, there is one first ground terminal 201 arranged every two first signal terminals 202. Similarly, the second row of terminals 30 includes the second ground terminal 301 arranged between the signal terminals 302, that is, the second ground terminal 301 and the second signal terminal 302 of the second row of terminals 30 are arranged alternately with each other. As better shown in FIGS. 5 and 6, there is one second ground terminal 301 arranged every two second signal terminals 302. It should be understood that the arrangement of the ground terminals and the signal terminals of the two rows of terminals is not limited to this. For example, there may be one ground terminal arranged every one or more than two signal terminals, or even each row of terminals may only include one ground terminal, and all other terminals are signal terminals, and vice versa.

As shown in FIG. 3, the electrical connector 1 further includes a first terminal fixing member 21 and a second terminal fixing member 31. The first ground terminal 201 and the first signal terminal 202 of the first row of terminals 20 extend through the first terminal fixing member 21 and are fixed by the first terminal fixing member, and the second ground terminal 301 and the second signal terminal 302 of the second row of terminals 30 extend through the second terminal fixing member 31 and are fixed by the second terminal fixing member. Thus, the first ground terminal 201 and the first signal terminal 202 of the first row of terminals 20 are fixed by the first terminal fixing member 21 and arranged alternately with each other, and are divided by the first terminal fixing member 21 into a first portion adapted to be in contact with the corresponding terminals of the mated electrical connector and a second portion extending out of the housing 10 of the electrical connector to be connected to the circuit board. The second ground terminal 301 and the second signal terminal 302 of the second row of terminals 30 are fixed by the second terminal fixing member 31 and arranged alternately with each other, and are divided by the second terminal fixing member 31 into a first portion adapted to be in contact with the corresponding terminals of the mated electrical connector and a second portion extending out of the housing 10 of the electrical connector to be connected to the circuit board. The first terminal fixing member 21 and the second terminal fixing member 31 may be made of non-conductive materials, such as plastic. For example, the terminal fixing member may be molded on each row of terminals by plastic through an overmolding process.

In the illustrated embodiment, a position of the inserting end of the electrical connector 1 adapted to be connected with the mated electrical connector 2 and a position of ends of the signal terminal and the ground terminal leading out of the housing to be connected with the circuit board are located on two adjacent sides of the housing 10 of the electrical connector, respectively. Portions of the signal terminals 202, 302 and the ground terminals 201, 301 of the electrical connector away from the inserting end extend towards an interior of the housing. The portions are then bent towards a side wall of the housing to extend out of the housing, so as to be able to be electrically connected with the signal lead wire and the ground layer of the circuit board, respectively.

The electrical connector further includes a ground shield assembly at least partially positioned between the signal terminal of the first row of terminals 20 and the signal terminal of the second row of terminals 30, and configured to be directly or indirectly connected to the ground layer of the circuit board. The ground shield assembly is in contact with a corresponding ground terminal at at least one position of each ground terminal 201, 301 of at least one ground terminal of the first row of terminals 20 and/or the second row of terminals 30, so that the contacted ground terminal is divided into at least two sections in its extension direction by the at least one position. For example, the contacted ground terminal can be divided into two, three, four or more sections. Thus, a path of each section is shortened relative to a total path of the contacted ground terminal. As will be described in detail later, boundaries similar to a total reflection boundary is formed at contact positions of the contacted ground terminal, so that the resonant frequency of the ground terminal is increased due to the shortened distance of electrical boundary, thereby changing the resonant frequency of the ground terminal.

In the embodiment shown in FIGS. 3 to 7, the ground shield assembly of the electrical connector includes a conductive shield member 41, which is at least partially positioned between the signal terminal of the first row of terminals 20 and the signal terminal of the second row of terminals 30, but not in electrical contact with the signal terminals of the two rows of terminals. The conductive shield member is adapted to be directly electrically connected to the ground layer of the circuit board 3, for example, it is directly electrically connected to the ground layer of the circuit board 3 by a pin 412. The conductive shield member 41 is substantially plate-shaped, and its extension direction is substantially parallel to the first row of terminals 20 and the second row of terminals 30. In the embodiment shown in FIGS. 3 to 7, the plate-shaped conductive shield member 41 separates the first row of terminals 20 from the second row of terminals 30. Thus, the conductive shield member 41 eliminates the mutual signal interference between the signal terminals of the two rows of terminals, so that the near-end crosstalk is improved.

In the illustrated embodiment, the ground shield assembly further includes a positioning member 42 arranged within the housing 10, and the positioning member 42 fixedly positions the conductive shield member 41 between the first row of terminals 20 and the second row of terminals 30 relative to the housing. The positioning member 42 may be made of non-conductive materials. For example, it is overmolded on the conductive shield member 41 by plastic. As shown in FIG. 3, the positioning member 42 is overmolded in the middle of the conductive shield member 41, so that a plate-shaped portion 411 of the conductive shield member 41 is exposed from one side of the positioning member 42, and the pin 412 of the conductive shield member 41 is exposed from the other side of the positioning member 42.

In the illustrated embodiment, the ground shield assembly further includes at least one common ground member. Each common ground member is in contact with a corresponding ground terminal at at least two positions of each of at least one ground terminal of the first row of terminals 20 and/or the second row of terminals 30, so that the contacted ground terminal is divided into at least three sections in its extension direction by the at least two positions, and each common ground member is electrically connected with the conductive shield member 41. The at least one common ground member is not in electrical contact with the signal terminals of the first row of terminals 20 and the second row of terminals 30.

In the illustrated embodiment, the common ground member has a main body portion 501 extending in a first direction X (which is parallel to a terminal arrangement direction of the first row of terminals 20 or the second row of terminals 30) and a plurality of contact portions 502 extending from two side edges of the main body portion 501 in a second direction Y (which is perpendicular to the first direction X). A cross-section of the common ground member passing through the main body portion 501 and the contact portions 502 is in the form of substantially U-shaped or C-shaped shape.

The two contact portions 502 arranged opposite to each other in the second direction Y are in contact with a same ground terminal of the first row of terminals 20 or the second row of terminals 30. In addition, the main body portion 501 of the common ground member located at a base of the substantially U-shaped or C-shaped shape is positioned at a distance from the first row of terminals 20 and the second row of terminals 30. That is to say, the first row of terminals 20 and the second row of terminals 30 are respectively positioned away from the main body portion 501 and are not in contact with the main body portion 501. In the illustrated embodiment, the main body portion 501 of the first common ground member 50a-1 located at a base of the substantially U-shaped or C-shaped shape is separated from the first ground terminal 201 by the first terminal fixing member 21; and the main body portion 501 of the second common ground member 50b-1 located at a base of the substantially U-shaped or C-shaped shape is separated from the second ground terminal 301 by the second terminal fixing member 31. The main body portion 501 located at the base of the substantially U-shaped or C-shaped shape has a larger planar area and lower impedance, and a potential of the main body portion 501 is similar to that of the ground layer, which facilitates the noise with higher potential entering into the main body portion.

As shown in FIGS. 3, 6 and 7, the at least one common ground member includes a first common ground member 50a-1 and a second common ground member 50b-1. The first common ground member 50a-1 and the second common ground member 50b-1 have substantially the same structure, and respectively include a main body portion 501 extending in the first direction X and a plurality of contact portions 502 extending from side edges of the main body portion 501. As better shown in FIG. 7, the cross-sections of each of the first common ground member 50a-1 and the second common ground member 50b-1 passing through the main body portion 501 and the contact portions 502 are in the form of substantially U-shaped shape, so that the main body portion 501 is located at the bottom of the U-shaped shape and is not in contact with the corresponding ground terminal. The contact portions 502 can be in contact with the corresponding ground terminal at two positions in the extension direction of the corresponding ground terminal. The first common ground member 50a-1 and the second common ground member 50b-1 are not in electrical contact with the signal terminals of the two rows of terminals.

The first common ground member 50a-1 is provided on the outer side of the first row of terminals 20 away from the second row of terminals 30, and is in contact with a corresponding first ground terminal at two positions in the extension direction of each first ground terminal 201. The second common ground member 50b-1 is provided on the outer side of the second row of terminals 30 away from the first row of terminals 20, and is in contact with a corresponding second ground terminal at two positions in the extension direction of each second ground terminal 301. In other words, the first row of terminals 20 and the second row of terminals 30 are sandwiched between the first common ground member 50a-1 and the second common ground member 50b-1.

As better shown in FIGS. 3 and 6, the first common ground member 50a-1 and the second common ground member 50b-1 each includes a connecting leg 503, which extends from an end of the main body portion 501 in the first direction X to the conductive shield member 41 to be in electrical contact with the conductive shield member. For example, the connecting leg 503 of the first common ground member 50a-1 may extend from its main body portion 501 across the first terminal fixing member 21 to one side of the plate-shaped portion 411 of the conductive shield member 41, so as to be in electrical contact with the conductive shield member 41, and the connecting leg 503 of the second common ground member 50b-1 may extend from its main body portion 501 across the second terminal fixing member 31 to the other side of the plate-shaped portion 411 of the conductive shield member 41, so as to be in electrical contact with the conductive shield member 41.

The assembling process will be simpler, and the gap tolerance of the terminals is advantageously controlled by providing the first common ground member 50a-1 and the second common ground member 50b-1 on the outer sides of the first row of terminals 20 and the second row of terminals 30, respectively.

As shown in FIGS. 6 and 7, the first common ground member 50a-1 is positioned on a side of the first terminal fixing member 21 opposite to the conductive shield member 41, so that the first common ground member 50a-1 crosses the first terminal fixing member 21 to be in electrical contact with two separated sections of each first ground terminal 201. The first common ground member 50a-1 may be positioned on the side of the first terminal fixing member 21 opposite to the conductive shield member 41 by a positioning portion located on the first terminal fixing member 21. As shown in FIG. 7, the first common ground member 50a-1 is in contact with the first ground terminal 201 at a first contact point A1 and a second contact point A2 on both sides of the first terminal fixing member 21 by the contact portions 502. Thus, the first contact point A1 and the second contact point A2 may divide the first ground terminal 201 into three sections, so that a path of each section is shortened relative to a total path of the first ground terminal.

The second common ground member 50b-1 is positioned on a side of the second terminal fixing member 31 opposite to the conductive shield member 41, so that the second common ground member 50b-1 crosses the second terminal fixing member 31 to be in electrical contact with two separated sections of each second ground terminal 301. As shown in FIG. 7, the second common ground member 50b-1 is in contact with the second ground terminal 301 at a third contact point B1 and a fourth contact point B2 on both sides of the second terminal fixing member 31 by the contact portions 502. Thus, the third contact point B1 and the fourth contact point B2 may divide the second ground terminal 301 into three sections, so that a path of each section is shortened relative to the total path of the second ground terminal.

The first ground terminal 201 is connected to the ground layer of the circuit board by the first common ground member 50a-1 and the conductive shield member 41 of the ground shield assembly. The second ground terminal 301 is connected to the ground layer of the circuit board by the second common ground member 50b-1 and the conductive shield member 41 of the ground shield assembly. The potential or noise generated by the first ground terminal 201 not only flow into the ground layer of the circuit board along the first ground terminal 201, but also flow into the ground layer of the circuit board by the first common ground member 50a-1 and the conductive shield member 41 via the first contact point A1 and the second contact point A2, respectively. More specifically, the potential or noise generated in the three sections of the first ground terminal 201 divided by the first contact point A1 and the second contact point A2 can flow into the contact portions 502 of the first common ground member 50a-1 via the first contact point A1 and the second contact point A2, respectively, and then into the conductive shield member 41 via the connecting leg 503 of the common ground member, and finally into the ground layer of the circuit board via the pin 412 of the conductive shield member 41. Similarly, the potential or noise induced in the second ground terminal 301 not only flow into the ground layer of the circuit board along the second ground terminal 301, but also flow into the ground layer of the circuit board by the second common ground member 50b-1 and the conductive shield member 41 via the third contact point B1 and the fourth contact point B2, respectively. In addition, the main body portions 501 of the common ground member positioned at a distance from the first ground terminal 201 and the second ground terminal 301 have a larger planar area and lower impedance, further facilitating the flow of the potential or noise away from the signal terminals and into the corresponding common ground member.

Because the boundaries similar to the total reflection boundary are formed at the first contact point A1 and the second contact point A2 of the first ground terminal 201, as well as at the third contact point B1 and the fourth contact point B2 of the second ground terminal 301, the resonant frequency of the ground terminal is increased due to the shortened distance between the electrical boundaries, thereby changing the resonant frequency of the ground terminal. Thus, the resonant frequency point of the ground terminal is increased to a higher frequency point, thereby improving the high-frequency resonance of the electrical connector.

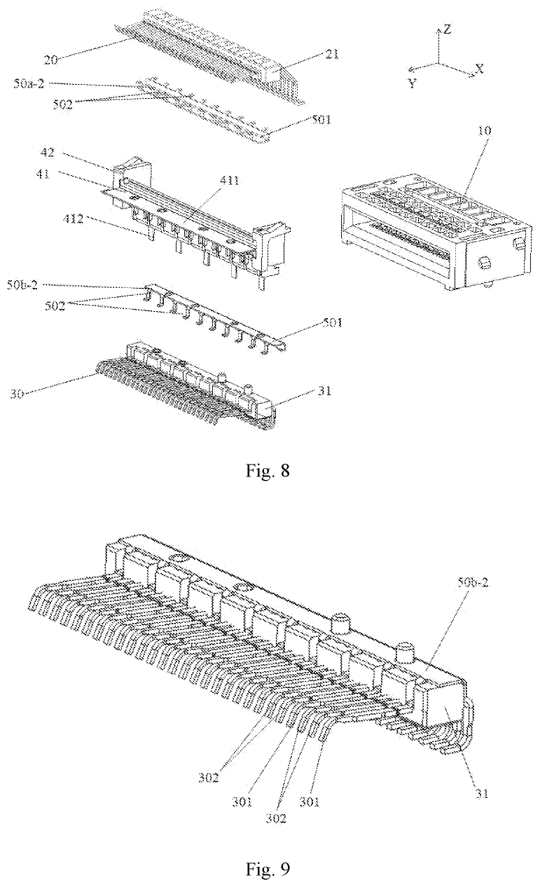

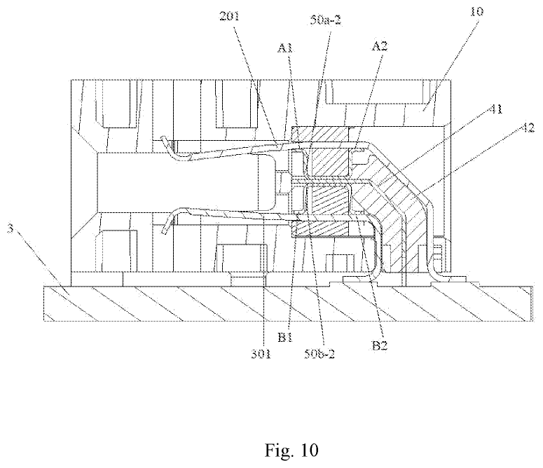

FIG. 8 is an exploded view of an electrical connector according to another embodiment of the present disclosure. FIG. 9 is a perspective view of a second row of terminals of the electrical connector assembled together with a common ground member. FIG. 10 shows a sectional view of the electrical connector. FIGS. 8 to 10 will be discussed together by referring to FIGS. 1 to 7.

In the embodiment of FIGS. 8 to 10, the configurations of the housing, the first row of terminals, and the second row of terminals (as well as the ground terminal and the signal terminal of each row of terminals) of the electrical connector are substantially similar to those of the housing 10, the first row of terminals 20, and the second row of terminals 30 (as well as the ground terminal and the signal terminal of each row of terminals) of the electrical connector shown in FIGS. 3 to 7. The same or similar structure will not be repeated here.

The difference between the electrical connector of the embodiment of FIGS. 8 to 10 and the electrical connector of FIGS. 3 to 7 lies in the ground shield assembly. Although the ground shield assembly of the electrical connector shown in FIGS. 8 to 10 includes a conductive shield member 41 and a positioning member 42 with a structure substantially similar to that of the conductive shield member and the positioning member of the ground shield assembly shown in FIGS. 3 to 7, the structure and arrangement position of the common ground member of the ground shield assembly of the electrical connector shown in FIGS. 8 to 10 are different from those of the common ground member of the electrical connector shown in FIGS. 3 to 7.

Specifically, the first common ground member 50a-2 includes a main body portion 501 extending in a first direction X (which is parallel to a terminal arrangement direction of the first row of terminals 20) and a plurality of contact portions 502 extending from two side edges of the main body portion 501 in a second direction Y (which is perpendicular to the first direction), and the second common ground member 50b-2 includes a main body portion 501 extending in the first direction X and a plurality of contact portions 502 extending from two side edges of the main body portion 501 in the second direction Y. A cross-section of each of the first common ground member 50a-2 and the second common ground member 50b-2 passing through the main body portion 501 and the contact portions 502 is in the form of a substantially U-shaped or C-shaped shape. As shown in FIG. 10, two contact portions 502 arranged opposite to each other in the extension direction of the ground terminal are in contact with a same ground terminal of a row of terminals. In addition, the main body portion 501 located at the base of the substantially U-shaped or C-shaped shape is positioned at a distance from the first ground terminal 201 and the second ground terminal 301, and is not in contact with the first ground terminal 201 and the second ground terminal 301. In the illustrated embodiment, the main body portion 501 located at the base of the substantially U-shaped or C-shaped shape of the first common ground member 50a-1 is separated from the first ground terminal 201 by the first terminal fixing member 21; and the main body portion 501 located at the base of the substantially U-shaped or C-shaped shape of the second common ground member 50b-1 is separated from the second ground terminal 301 by the second terminal fixing member 31. In addition, the main body 501 has a larger planar area and lower impedance, and a potential of the main body portion 501 is similar to that of the ground layer, which facilitates the noise with higher potential entering into the main body portion.

Furthermore, as better shown in FIGS. 8 and 10, the first common ground member 50a-2 and the second common ground member 50b-2 do not include a connecting leg that is similar to the connecting leg 503 of the common ground member in the embodiment as shown in FIGS. 3 to 7.

Correspondingly, as better shown in FIG. 10, the first common ground member 50a-2 is provided on the inner side of the first row of terminals 20 facing the second row of terminals 30, and is in contact with the corresponding first ground terminal at two positions in the extension direction of each first ground terminal 201. The first common ground member 50a-2 is positioned on a side of the first terminal fixing member 21 facing the conductive shield member 41, so that the first common ground member 50a-2 crosses the first terminal fixing member 21 to be in electrical contact with two separated sections of each first ground terminal 201. The second common ground member 50b-2 is provided on the inner side of the second row of terminals 30 facing the first row of terminals 20, and is in contact with the corresponding second ground terminal at two positions in the extension direction of each second ground terminal 301. The second common ground member 50b-2 is positioned on a side of the second terminal fixing member 3 facing the conductive shield member 41, so that the second common ground member 50b-2 crosses the second terminal fixing member 31 to be in electrical contact with two separated sections of each second ground terminal 301. Similarly, the common ground members are not in electrical contact with the signal terminals of the two rows of terminals.

In other words, the first common ground member 50a-2 and the second common ground member 50b-2 are sandwiched between the first row of terminals 20 and the second row of terminals 30. Specifically, the base of the U-shaped shape of the first common ground member 50a-2 and the base of the U-shaped shape of the second common ground member 50b-2 are sandwiched between the first terminal fixing member 21 and the second terminal fixing member 31, and the base of the U-shaped shape of the first common ground member 50a-2 and the base of the U-shaped shape of the second common ground member 50b-2 are in contact with two opposite sides of the conductive shield member 41, specifically, in contact with two opposite sides of the plate-shaped portion 411 of the conductive shield member 41. Thus, the contact area between the first common ground member 50a-2 and the second common ground member 50b-2 and the conductive shield member 41 is larger, which greatly improves the resonance, cross talk, and return loss.

As shown in FIG. 10, the first common ground member 50a-2 is in contact with the first ground terminal 201 at the first contact point A1 and the second contact point A2 on both sides of the first terminal fixing member 21 by the contact portions 502, respectively. Thus, the first contact point A1 and the second contact point A2 may divide the first ground terminal 201 into three sections, so that a path of each section is shortened relative to the total path of the first ground terminal. Similarly, the second common ground member 50b-2 is in contact with the second ground terminal 301 at the third contact point B1 and the fourth contact point B2 on both sides of the second terminal fixing member 31 by the contact portions 502, respectively. Thus, the third contact point B1 and the fourth contact point B2 may divide the second ground terminal 301 into three sections, so that a path of each section is shortened relative to the total path of the second ground terminal.

The first ground terminal 201 is connected to the ground layer of the circuit board by the first common ground member 50a-2 and the conductive shield member 41 of the ground shield assembly. The second ground terminal 301 is connected to the ground layer of the circuit board by the second common ground member 50b-2 and the conductive shield member 41 of the ground shield assembly. The potential or noise induced in the first ground terminal 201 flow into the ground layer of the circuit board not only along the first ground terminal 201, but also by the first common ground member 50a-2 and the conductive shield member 41 via the first contact point A1 and the second contact point A2, respectively. More specifically, the potential or noise generated in each of the three sections of the first ground terminal 201 divided by the first contact point A1 and the second contact point A2 can flow into the contact portions 502 of the first common ground member 50a-2 via the first contact point A1 and the second contact point A2, respectively, and then into the conductive shield member 41 at the base of the U-shaped shape of the first common ground member 50a-2, and finally into the ground layer of the circuit board via the pin 412 of the conductive shield member 41. Similarly, the potential or noise induced in the second ground terminal 301 can flow into the ground layer of the circuit board not only along the second ground terminal 301, but can also by the second common ground member 50b-1 and the conductive shield member 41 via the third contact point B1 and the fourth contact point B2, respectively.

Boundaries similar to the total reflection boundary are formed at the first contact point A1 and the second contact point A2 of the first ground terminal 201, as well as at the third contact point B1 and the fourth contact point B2 of the second ground terminal 301, respectively, so that the resonant frequency of the ground terminal is increased due to the shortening of the distance of the electrical boundaries, thereby changing the resonant frequency of the ground terminal. That is, the resonant frequency point of the ground terminal is increased to a higher frequency point, thereby improving the high-frequency resonance of the electrical connector.

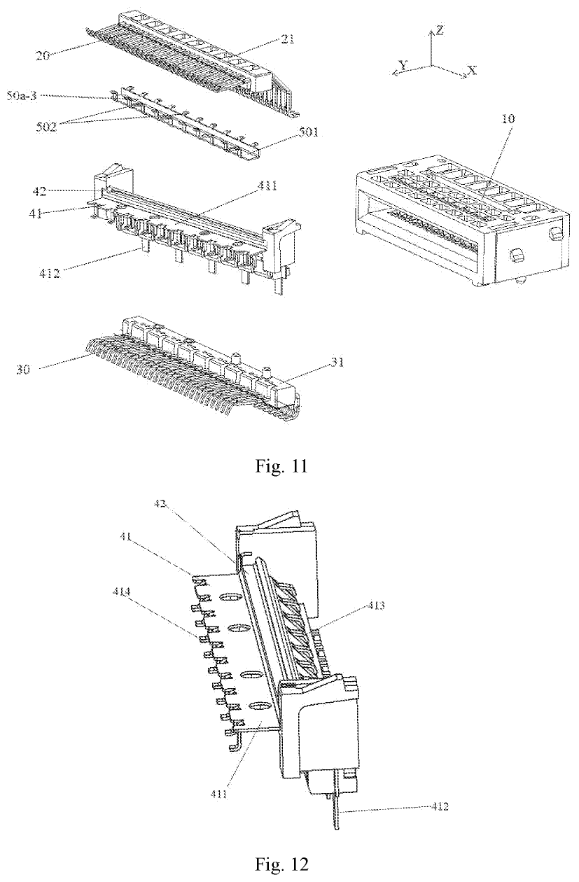

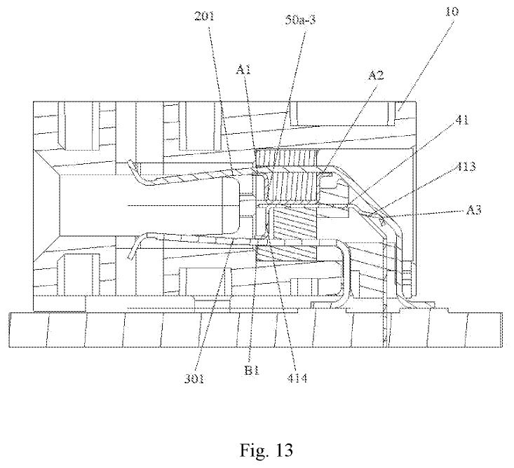

FIG. 11 is an exploded view of an electrical connector according to another embodiment of the present disclosure. FIG. 12 is a perspective view of a conductive shield member with a positioning member of the electrical connector. FIG. 13 shows a sectional view of the electrical connector. FIGS. 11 to 13 will be discussed together.

In the embodiment shown in FIGS. 11 to 13, the configurations of the housing, the first row terminals and the second row of terminals (as well as the ground terminal and the signal terminal of each row of terminals) of the electrical connector are substantially similar to those of the housing, the first row terminals and the second row of terminals (as well as the ground terminal and the signal terminal of each row of terminals) of the electrical connector in the aforementioned embodiments. The same or similar structures will not be repeated here.

The electrical connector of the embodiment shown in FIGS. 11 to 13 differs from the aforementioned embodiments in terms of the ground shield assembly. Specifically, the ground shield assembly of the embodiment shown in FIGS. 11 to 13 includes a conductive shield member 41 and only one common ground member 50a-3. The common ground member 50a-3 is in contact with one of the first ground terminal 201 and the second ground terminal 301; and in the embodiment shown in FIGS. 11 to 13, the common ground member 50a-3 is in contact with the first ground terminal 201. In addition, the conductive shield member 41 is in electrical contact with the first ground terminal 201 and the second ground terminal 301 by a shield member contact portion on both sides of the conductive shield member, respectively. Similarly, the conductive shield member 41 and the common ground member 50a-3 are not in electrical contact with the signal terminals of the two rows of terminals.

As shown in FIG. 11, the structure of the common ground member 50a-3 is similar to that of each of the first common ground member 50a-2 and the second common ground member 50b-2 shown in FIGS. 8 to 10. As shown in FIG. 13, the common ground member 50a-3 is provided on the inner side of the first row of terminals 20 facing the second row of terminals 30, and is in contact with the corresponding first ground terminal at two positions in the extension direction of each first ground terminal 201. Specifically, the common ground member 50a-3 is positioned on a side of the first terminal fixing member 21 facing the conductive shield member 41, so that the common ground member 50a-3 crosses the first terminal fixing member 21 to be in electrical contact with two separated sections of each first ground terminal 201. In other words, the common ground member 50a-3 is sandwiched between the conductive shield member 41 and the first row of terminals 20. Specifically, the base of the U-shaped shape of the common ground member 50a-3 is sandwiched between the first terminal fixing member 21 and the plate-shaped portion 411 of the conductive shield member 41. Thus, the contact area between the common ground member 50a-3 and the conductive shield member 41 is larger, which greatly improves the resonance, cross talk, and return loss.

In addition, the common ground member 50a-3 is in contact with the first ground terminal 201 at the first contact point A1 and the second contact point A2 on both sides of the first terminal fixing member 21 by the contact portions 502, respectively. Thus, the first contact point A1 and the second contact point A2 may divide the first ground terminal 201 into three sections, so that a path of each section is shortened relative to the total path of the first ground terminal.

Furthermore, the conductive shield member 41 is further in electrical contact with one ground terminal at at least one position, so that the one ground terminal is divided into at least four sections in its extension direction by the positions where the ground terminal is in contact with the conductive shield member 41 or the common ground member 50a-3. As better shown in FIG. 13, the conductive shield member 41 is in electrical contact with the first ground terminal 201 by a first shield member contact portion 413 at a third contact point A3. Thus, the first ground terminal 201 is divided into four sections by the first contact point A1, the second contact point A2, and the third contact point A3. Thus, the potential or noise induced in the first ground terminal 201 can flow into the ground layer of the circuit board not only along the first ground terminal 201, but can also by the common ground member 50a-3 and the conductive shield member 41 via the first contact point A1, the second contact point A2, and the third contact point A3, respectively. More specifically, the potential or noise generated in each of the four sections of the first ground terminal 201 divided by the first contact point A1, the second contact point A2, and the third contact point A3 can not only flow into the common ground member 50a-3 via the first contact point A1 and the second contact point A2 and then into the conductive shield member 41 at the base of the U-shaped shape of the common ground member 50a-3, but also flow into the conductive shield member 41 by the first shield member contact portion 413 via the third contact point A3, and finally into the ground layer of the circuit board by the pin 412 of the conductive shield member 41.

As shown in FIG. 12, the conductive shield member 41 includes a shield member body 410, a first shield member contact portion 413 and a second shield member contact portion 414. The shield member contact portions 413, 414 extend from two opposite sides of the shield member body 410, so as to be in electrical contact with the corresponding ground terminal. As shown in the figure, the first shield member contact portion 413 and the second shield member contact portion 414 are located on two opposite sides of the shield member body 410, respectively, and are formed in the form of an elastic arm so as to be in contact with the first ground terminal 201 and the second ground terminal 301, respectively.

Preferably, the conductive shield member 41 is formed with a positioning member 42, which may be made of non-conductive materials. The positioning member 42 fixedly positions the conductive shield member 41 between the first row of terminals 20 and the second row of terminals 30 to separate them. As shown in FIG. 12, the positioning member 42 is overmolded in the middle of the conductive shield member 41. The positioning member 42 is formed with a corresponding opening, so that the first shield member contact portion 413 can pass through the opening to be in contact with the first ground terminal 201. The plate-shaped portion 411 of the conductive shield member 41, which is not covered by the positioning member 42, is formed with the second shield member contact portion 414.

The conductive shield member 41 is in electrical contact with the second ground terminal 301 at at least one position in the extension direction of the second ground terminal, so that the contacted second ground terminal is divided into at least two sections in its extension direction by the position where the second ground terminal is in contact with the conductive shield member 41. As better shown in FIG. 13, the second shield member contact portion 414 of the conductive shield member 41 is in electrical contact with the second ground terminal 301 at a fourth contact point B1. The fourth contact point B1 divides the second ground terminal 301 into two sections in the extension direction of this ground terminal. Thus, the potential or noise induced in the second ground terminal 301 can flow into the ground layer of the circuit board not only along the second ground terminal 301, but also by the conductive shield member 41 via the fourth contact point B1. In addition, both the main body portion 501 of the common ground member, which is positioned at a distance from the first ground terminal 201 (such as by the first terminal member 21) and the conductive shield member 41 have a larger planar area and lower impedance, further facilitating the flow of potential or noise away from the signal terminals and into the corresponding common ground member.

Boundaries similar to the total reflection boundary are formed at the first contact point A1, the second contact point A2, and the third contact point A3 of the first ground terminal 201, as well as at the fourth contact point B1 of the second ground terminal 301, respectively, so that the resonant frequency of the ground terminal is increased due to the shortening of the distance between the electrical boundaries, thereby changing the resonant frequency of the ground terminal. That is to say, the resonant frequency point of the ground terminal is increased to a higher frequency point, thereby improving the high-frequency resonance of the electrical connector.

In an embodiment not shown, a ground shield assembly of the electrical connector includes a conductive shield member 41, but does not include common ground members. In this case, the conductive shield member 41 is substantially similar to the conductive shield member shown in FIGS. 11 to 13. The first shield member contact portion 413 and the second shield member contact portion 414 of the conductive shield member are located on two opposite sides of the shield assembly body 410, respectively, and are formed in the form of an elastic arm, so as to be in contact with the first ground terminal 201 and the second ground terminal 301, respectively. In this case, the first shield member contact portion 413 divides the first ground terminal 201 into two sections, and the second shield member contact portion 414 divides the second ground terminal 301 into two sections. Similarly, boundaries similar to the total reflection boundary are formed at the contact point between the first shield member contact portion 413 and the first ground terminal 201, as well as at the contact point between the second shield member contact portion 414 and the second ground terminal 301, respectively, so that the resonant frequency of the ground terminal is increased due to the shortening of the distance between the electrical boundaries, thereby changing the resonant frequency of the ground terminal, and the resonant frequency point of the ground terminal is increased to a higher frequency point, thereby improving the high-frequency resonance of the electrical connector.

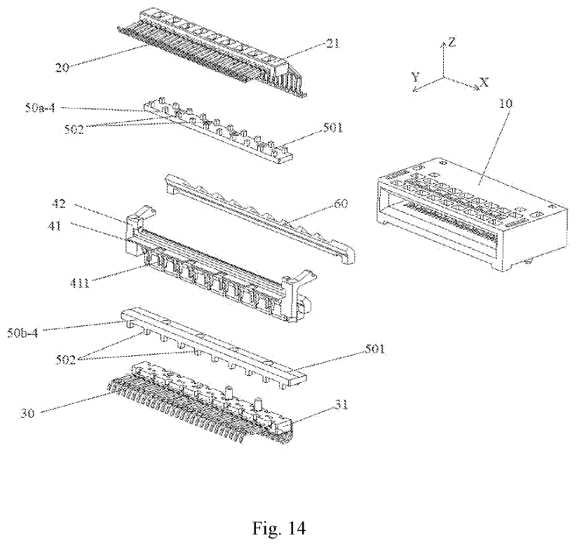

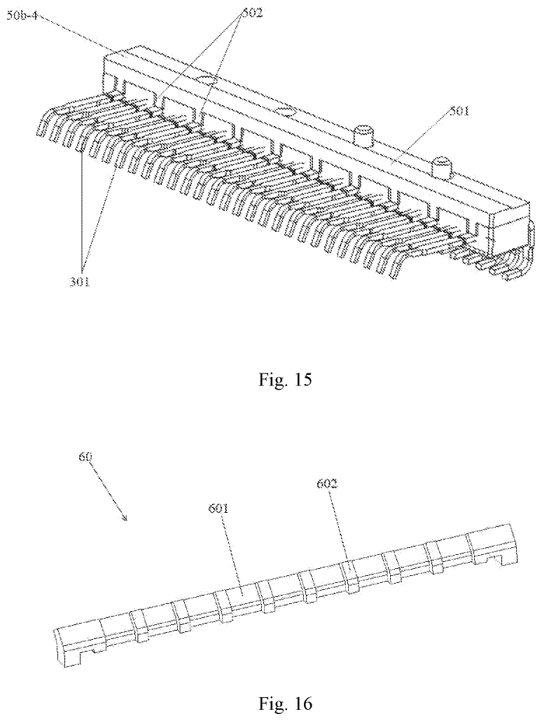

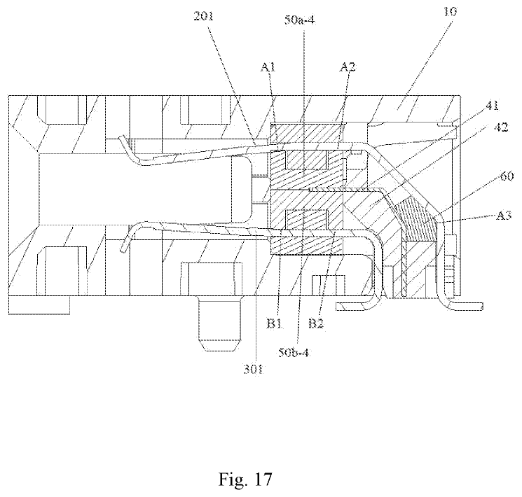

FIG. 14 is an exploded view of an electrical connector according to another embodiment of the present disclosure. FIG. 15 is a perspective view of a second row of terminals s of the electrical connector assembled together with a common ground member. FIG. 16 is a perspective view of a third common ground member of the electrical connector. FIG. 17 is a sectional view of the electrical connector. FIGS. 14 to 17 will be discussed together.

In the embodiment of FIGS. 14 to 17, the configurations of the housing, the first row terminals and the second row of terminals (as well as the ground terminal and the signal terminal of each row of terminals) of the electrical connector are substantially similar to those of the housing 10, the first row terminals 20 and the second row of terminals 30 (as well as the ground terminal and the signal terminal of each row of terminals) of the electrical connector in the aforementioned embodiments. The same or similar structures will not be repeated here.

The electrical connector of the embodiments of FIGS. 14 to 17 differs from the aforementioned embodiments in the ground shield assembly. The structure of the conductive shield member of the ground shield assembly in the embodiment shown in FIGS. 14 to 17 is substantially similar to that of the conductive shield member 41 in the embodiment shown in FIGS. 8 to 10.

The ground shield assembly of the embodiment shown in FIGS. 14 to 17 includes a first common ground member 50a-3 and a second common ground member 50b-3. The contact portion 502 of each common ground member is formed as a protrusion protruding from a surface of the main body portion 501 facing the first row of terminals 20 or the second row of terminals 30. Similar to the embodiment shown in FIGS. 8 to 10, the first common ground member 50a-3 is provided on the inner side of the first row of terminals 20 facing the second row of terminals 30, and is in contact with the corresponding first ground terminal at two positions in the extension direction of each first ground terminal 201. The first common ground member 50a-3 is positioned on a side of the first terminal fixing member 21 facing the conductive shield member 41, so that the first common ground member 50a-3 crosses the first terminal fixing member 21 so as to be in electrical contact with two separated sections of each first ground terminal 201. The second common ground member 50b-3 is provided on the inner side of the second row of terminals 30 facing the first row of terminals 20, and is in contact with the corresponding second ground terminal at two positions in the extension direction of each second ground terminal 301. The second common ground member 50b-3 is positioned on a side of the second terminal fixing member 31 facing the conductive shield member 41, so that the second common ground member 50b-3 crosses the second terminal fixing member 31 so as to be in electrical contact with two separated sections of each second ground terminal 301. The first common ground member 50a-3 and the second common ground member 50b-3 are also sandwiched between the first row of terminals 20 and the second row of terminals 30. In addition, as better shown in FIG. 17, the plate-shaped portion 411 of the electrical shield member 41 is partially sandwiched between the first common ground member 50a-3 and the second common ground member 50b-3. The first common ground member 50a-3 and the second common ground member 50b-3 are not in electrical contact with the signal terminals of the two rows of terminals.

In addition, the ground shield assembly of the embodiment shown in FIGS. 14 to 17 further includes a third common ground member 60. A length of the first ground terminal 201 of the electrical connector shown in FIGS. 14 to 17 is longer than that of the second ground terminal 301, and there is a gap between a portion of the first ground terminal 201 and the conductive shield member 41. The third common ground member 60 is provided in the gap to directly contact each first ground terminal 201 of the first row of terminals 20 and the conductive shield member 41, so that each first ground terminal 201 is divided into four sections in its extension direction by the positions where the first ground terminal is in contact with the first common ground member 50a-4 and the third common ground member 60. Similarly, the third common ground member 60 is not in electrical contact with the signal terminals of the two rows of terminals.

As better shown in FIG. 17, the first ground terminal 201 is not only in contact with the first common ground member 50a-4 at the first contact point A1 and the second contact point A2, but also in contact with the third common ground member 60 at the third contact point A3. Therefore, the potential or noise generated in the first ground terminal 201 will flow into the conductive shield member 41 via the first contact point A1, the second contact point A2, and the third contact point A3, respectively, and then into the ground layer of the circuit board. In addition, the second ground terminal 301 is in contact with the second common ground member 50b-3 at the fourth contact point B1 and the fifth contact point B2. The potential or noise generated in the second ground terminal 301 will flow into the conductive shield member 41 via the fourth contact point B1 and the fifth contact point B2, respectively, and then into the ground layer of the circuit board. The main body portion 501 of the common ground member, which is positioned at a distance from the first ground terminal 201 and the second ground terminal 301 by the corresponding terminal fixing members 21 or 31, has a larger planar area and lower impedance, further facilitating the flow of potential or noise away from the signal terminal and into the corresponding common ground member.

Thus, boundaries similar to the total reflection boundary are formed at the first contact point A1, the second contact point A2, and the third contact point A3 of the first ground terminal 201, as well as at the fourth contact point B1 and the fifth contact point B2 of the second ground terminal 301, respectively, so that the resonant frequency of the ground terminal is increased due to the shortening of the distance between the electrical boundaries, thereby changing the resonant frequency of the ground terminal. That is to say, the resonant frequency point of the ground terminal is increased to a higher frequency point, thereby improving the high-frequency resonance of the electrical connector.

As better shown in FIG. 16, the third common ground member 60 includes a body 601 extending in the first direction X parallel to the terminal arrangement direction of the first row of terminals 20 and a plurality of protrusions 602 protruding from a surface of the body facing the first row of terminals 20. The body 601 is adapted to be in contact with the conductive shield member 41, and each protrusion 602 is adapted to be in contact with the first ground terminal 201.

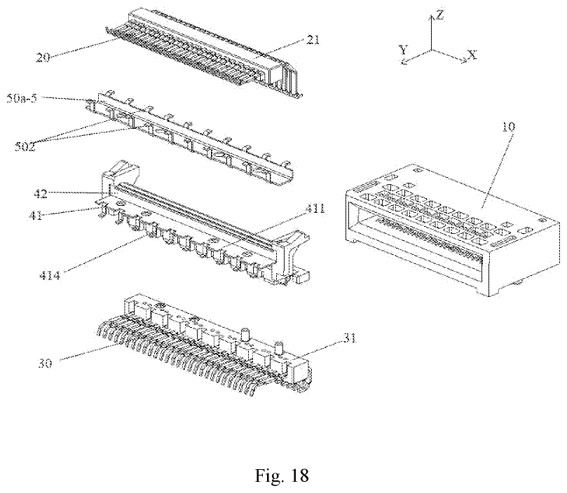

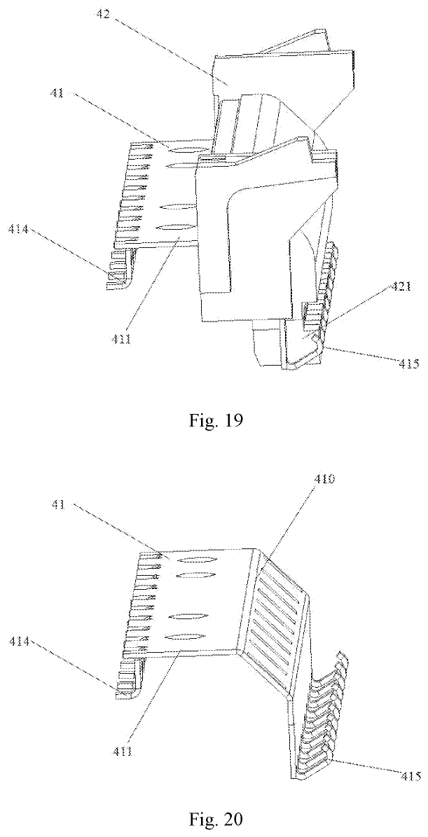

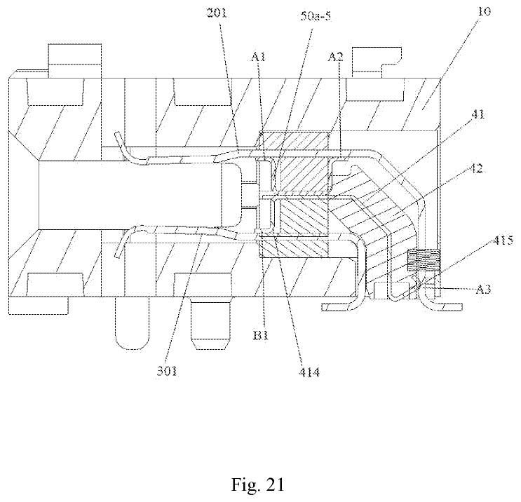

FIG. 18 shows an exploded view of an electrical connector according to an embodiment of the present disclosure. FIG. 19 shows a perspective view of a conductive shield member with a positioning member of the electrical connector. FIG. 20 shows a perspective view of a conductive shield member of the electrical connector. FIG. 21 shows a sectional view of the electrical connector. FIGS. 19 to 21 will be discussed together.

The configurations of the housing, the first row terminals, and the second row of terminals (as well as the ground terminal and the signal terminal of each row of terminals) of the electrical connector in the embodiment shown in FIGS. 19 to 21 are substantially similar to those of the housing 10, the first row terminals 20, and the second row of terminals 30 (as well as the ground terminal and the signal terminal of each row of terminals) of the electrical connector in the aforementioned embodiments. The same or similar structures will not be repeated here.

The electrical connectors of the embodiment shown in FIGS. 19 to 21 differs from the aforementioned embodiments in terms of the ground shield assembly. The ground shield assembly of the electrical connector shown in FIGS. 19 to 21 includes a conductive shield member 41 and only one common ground member 50a-5.

The conductive shield member 41 is positioned between the first row of terminals 20 and the second row of terminals 30. However, unlike the aforementioned embodiments, the conductive shield member 41 is not directly connected to the ground layer of the circuit board, but is in contact with the first ground terminal 201 by the first shield member contact portion in the form of an elastic arm or the first shield member contact arm 415 located at an end of the conductive shield member, and is indirectly connected to the ground layer of the circuit board via the first ground terminal 201. Therefore, in this case, the conductive shield member 41 does not extend out of the housing 10 of the electrical connector. The conductive shield member 41 also is not in electrical contact with the signal terminals of the two rows of terminals.

As better shown in FIGS. 19 and 20, the conductive shield member 41 includes a shield member body 410, a first shield member contact portion or first shield member contact arm 415, and a second shield member contact portion 414. The shield member contact portions 415, 414 extend from the shield member body 410 to be in electrical contact with the corresponding ground terminals. As shown in the figure, the first shield member contact portion 415 and the second shield member contact portion 414 are located at two opposite ends of the shield member body 410, and are formed in the form of an elastic arm, so as to be in contact with the first ground terminal 201 and the second ground terminal 301, respectively.

As shown in FIGS. 19 to 21, the conductive shield member 41 is formed with a positioning member 42, and the positioning member 42 may be made of non-conductive materials. The positioning member 42 fixedly positions the conductive shield member 41 between the first row of terminals 20 and the second row of terminals 30 to separate them. As shown in FIG. 19, the positioning member 42 includes a dividing portion 421 configured to separate the first shield member contact portions 415 from each other.

The ground shield assembly in the embodiment shown in FIGS. 18 to 21 includes a conductive shield member 41 and only one common ground member 50a-5. The common ground member 50a-5 is in contact with one of the first ground terminal 201 and the second ground terminal 301. In the embodiment shown in FIGS. 18 to 21, the common ground member 50a-5 is in contact with the first ground terminal 201. Similarly, the common ground member 50a-5 is not in electrical contact with the signal terminals of the two rows of terminals.

As shown in FIG. 18, the structure of the common ground members 50a-5 is similar to that of each of the first common ground member and the second common ground member in the embodiments shown in FIGS. 8 to 10 and FIGS. 11 to 13. As better shown in FIG. 21, the common ground member 50a-5 is provided on the inner side of the first row of terminals 20 facing the second row of terminals 30, and is in contact with the corresponding first ground terminal at two positions in the extension direction of each first ground terminal 201. Specifically, the common ground member 50a-5 is positioned on a side of the first terminal fixing member 21 facing the conductive shield member 41, so that the common ground member 50a-5 crosses the first terminal fixing member 21 to be in electrical contact with the two separated sections of each first ground terminal 201. In other words, the common ground member 50a-5 is sandwiched between the conductive shield member 41 and the first row of terminals 20.

As shown in FIG. 21, the first ground terminal 201 is in contact with the common ground member 50a-5 by the contact portions 502 of the common ground member 50a-5 at the first contact point A1 and the second contact point A2, and is in contact with the conductive shield member 41 by the contact portion 415 of the conductive shield member 41 at the third contact point A3. Thus, the first ground terminal 201 is divided into four sections by the first contact point A1, the second contact point A2, and the third contact point A3. The second ground terminal 301 is in contact with the conductive shield member 41 by the second shield member contact portion 414 of the conductive shield member 41 at the fourth contact point B1. Thus, the second ground terminal 301 is divided into two sections by the fourth contact point B1.

The conductive shield member 41 and the main body portion 501 of the common ground member 50a-5, which is positioned at a distance from the first ground terminal 201 (such as by the first terminal fixing member 21), have a larger planar area and lower impedance, further facilitating the flow of the potential or noise away from the signal terminal and into the corresponding common ground member. Correspondingly, boundaries similar to the total reflection boundary are formed at the first contact point A1, the second contact point A2, and the third contact point A3 of the first ground terminal 201, as well as at the fourth contact point B1 of the second ground terminal 301, respectively, so that the resonant frequency of the ground terminal is increased due to the shortening of the distance between the electrical boundaries, thereby changing the resonant frequency of the ground terminal. That is to say, the resonant frequency point of the ground terminal is increased to a higher frequency point, thereby improving the high-frequency resonance of the electrical connector.

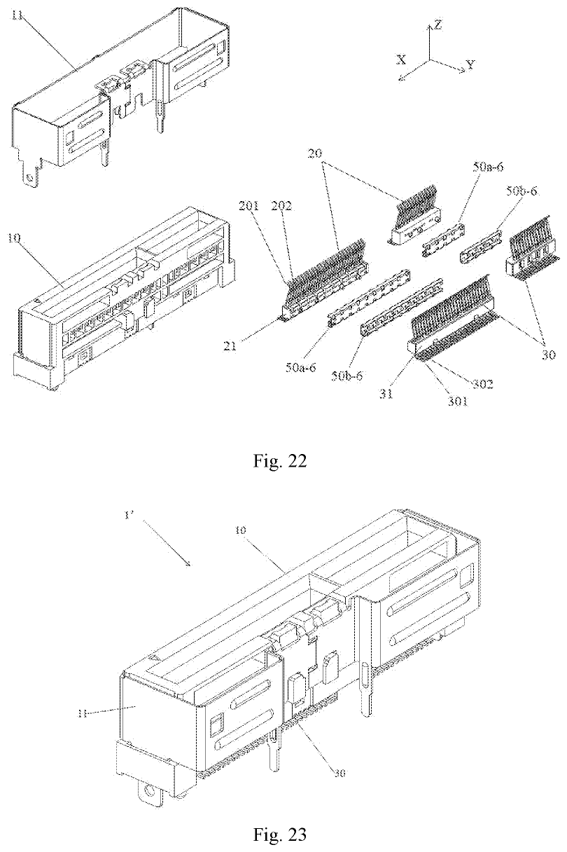

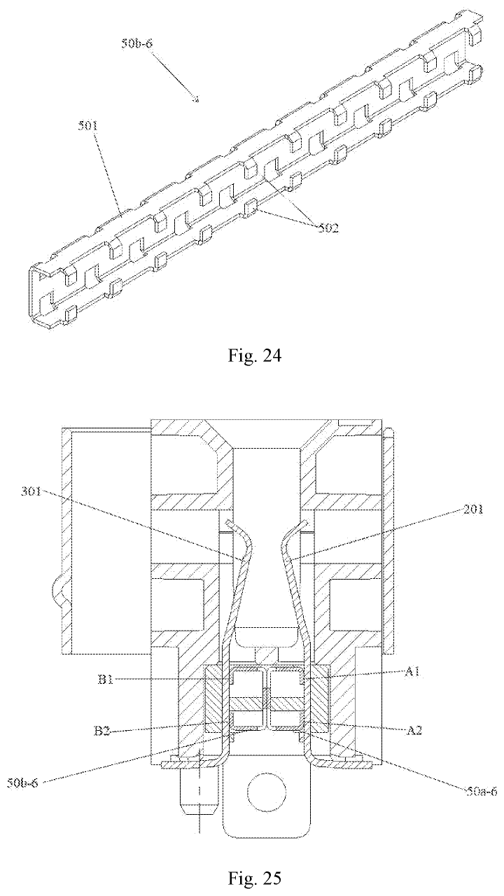

FIG. 22 shows an exploded view of an electrical connector according to another embodiment of the present disclosure. FIG. 23 shows a perspective view of the electrical connector after assembling. FIG. 24 shows a perspective view of a common ground member of the electrical connector. FIG. 25 shows a sectional view of the electrical connector.

The electrical connector shown in FIGS. 22 to 25 is different from the electrical connector in the aforementioned embodiments, and the electrical connector is a vertical electrical connector 1′. The vertical electrical connector 1′ has one end adapted to be installed on the circuit board 3 and the other end adapted to be mated with the mated electrical connector 2 opposite to the one end.

Similar to the aforementioned embodiments, the electrical connector 1′ includes a housing 10, a first row of terminals 20, and a second row of terminals 30. The first row of terminals 20 and the second row of terminals 30 are housed in the housing 10 separated from each other, and are adapted to be electrically connected with corresponding terminals of the mated electrical connector 2. The first row of terminals 20 includes a first ground terminal 201 adapted to be connected to a ground layer of the circuit board 3 and a first signal terminal 202 adapted to be connected to a signal lead wire of the circuit board 3; and the second row of terminals 30 includes a second ground terminal 301 adapted to be connected to the ground layer of the circuit board 3 and a second signal terminal 302 adapted to be connected to a signal lead wire of the circuit board 3.

The first row of terminals 20 includes a first ground terminal 201 arranged between the signal terminals 202. In other words, the first ground terminal 201 and the first signal terminal 202 of the first row of terminals 20 are arranged alternately with each other. Similarly, the second row of terminals 30 includes a second ground terminal 301 arranged between the signal terminals 302, that is, the second ground terminal 301 and the second signal terminal 302 of the second row of terminals 30 are arranged alternately with each other. It should be understood that the arrangements of the ground terminals and the signal terminals of the two rows of terminals is not limited to this. For example, there may be one ground terminal arranged every one or more than two signal terminals, or even each row of terminals may only include one ground terminal, and all other terminals are signal terminals; and vice versa.

As shown in FIG. 22, the electrical connector 1′ further includes a first terminal fixing member 21 and a second terminal fixing member 31. The first ground terminal 201 and the first signal terminal 202 of the first row of terminals 20 extend through the first terminal fixing member 21 and are fixed by the first terminal fixing member; and the second ground terminal 301 and the second signal terminal 302 of the second row of terminals 30 extend through the second terminal fixing member 31 and are fixed by the second terminal fixing member. Thus, the first ground terminal 201 and the first signal terminal 202 of the first row of terminals 20 are fixed by the first terminal fixing member 21 and arranged alternately with each other, and are divided by the first terminal fixing member 21 into a first portion adapted to be in contact with the corresponding terminals of the mated electrical connector and a second portion extending out of the housing 10 of the electrical connector to be connected to the circuit board. The second ground terminal 301 and the second signal terminal 302 of the second row of terminals 30 are fixed by the second terminal fixing 31 and arranged alternately with each other, and are divided by the second terminal fixing 31 into a first portion adapted to be in contact with the corresponding terminals of the mated electrical connector and a second portion extending out of the housing 10 of the electrical connector to be connected to the circuit board.

The first terminal fixing member 21 and the second terminal fixing member 31 may be made of non-conductive materials, such as plastic. For example, the terminal fixing member may be molded on each row of terminals by plastic through an overmolding process.

As shown in FIGS. 22 to 25, the electrical connector 1′ further includes at least one common ground member 50a-6, 50b-6, which is positioned between the signal terminal of the first row of terminals 20 and the signal terminal of the second row of terminals 30, and is in contact with the corresponding ground terminal at at least one position of each first ground terminal 201 of the first row of terminals 20 and each second ground terminal 301 of the second row of terminals 30, so that the contacted ground terminal is divided into at least two sections in its extension direction by the at least one position. For example, the ground terminal can be divided into two, three, four, or more sections, so that a path of each section is shortened relative to the total path of the contacted ground terminal. As will be described in detail later, boundaries similar to the total reflection boundary are formed at the contact position of the contacted ground terminal, so that the resonant frequency of the ground terminal is increased due to the shortening of the distance between the electrical boundaries, thereby changing the resonant frequency of the ground terminal.

In the illustrated embodiment, the at least one common ground member includes a first common ground member 50a-6 and a second common ground member 50b-6. As shown in FIG. 25, the first common ground member 50a-6 is provided on the inner side of the first row of terminals 20 facing the second row of terminals 30, and is in contact with the first ground terminal at two positions in the extension direction of each first ground terminal 201. The second common ground member 50b-6 is provided on the inner side of the second row of terminals 30 facing the first row of terminals 20, and is in contact with the second ground terminal at two positions in the extension direction of each second ground terminal 301. Similarly, the first common ground member 50a-6 and the second common ground member 50b-6 are not in electrical contact with the signal terminals of the two rows of terminals.

As shown in FIG. 22, the first common ground member 50a-6 and the second common ground member 50b-6 have substantially the same structure. As better shown in FIG. 24, the common ground members 50a-6, 50b-6 each includes a main body portion 501 extending in a first direction X (which is parallel to a terminal arrangement direction of the first row of terminals 20 or the second row of terminals 30) and a plurality of contact portions 502 extending from two side edges of the main body portion 501 in a second direction Y (which is perpendicular to the first direction X). A cross-section of the common ground member passing through the main body portion 501 and the contact portions 502 is in the form of substantially C-shaped or U-shaped shape.

As shown in FIG. 25, after the electrical connector 1′ is assembled, a base of the substantially C-shaped shape of the first common ground member 50a-6 is abutted against a base of the substantially C-shaped or U-shaped shape of the second common ground member 50b-6. The main body portion 501 located at the base of the substantially C-shaped or U-shaped shape is positioned at a distance from the first row of terminals 20 or the second row of terminals 30 and is not in contact with them. In the illustrated embodiment, the main body portion 501 located at the base of the substantially U-shaped or C-shaped shape of the first common ground member 50a-6 is separated from the first ground terminal 201 by the first terminal fixing member 21; and the main body portion 501 located at the base of the substantially U-shaped or C-shaped shape of the second common ground member 50b-6 is separated from the second ground terminal 301 by the second terminal fixing member 31. The two contact portions 502 arranged opposite to each other in the second direction Y are in contact with a same ground terminal of the first row of terminals 20 or a same ground terminal of the second row of terminals 30.

The first common ground member 50a-6 is positioned on a side of the first terminal fixing member 21 facing the second common ground member 50b-6, so that the first common ground member 50a-6 crosses the first terminal fixing member 21 to be in electrical contact with two separated sections of each first ground terminal 201. The second common ground member 50b-6 is positioned on a side of the second terminal fixing member 31 facing the first common ground member 50a-6, so that the second common ground member 50b-6 crosses the second terminal fixing member 31 to be in electrical contact with two separated sections of each second ground terminal 301.

As better shown in FIG. 25, the first ground terminal 201 is in contact with the contact portions 502 of the first common ground member 50a-6 at the first contact point A1 and the second contact point A2. Thus, the first contact point A1 and the second contact point A2 divide the first ground terminal 201 into three sections. The second ground terminal 301 is in contact with the contact portions 502 of the second common ground member 50b-6 at the third contact point B1 and the fourth contact point B2. Therefore, the third contact point B1 and the fourth contact point B2 divide the second ground terminal 301 into three sections.

The main body portions 501 of the common ground members 50a-6, 50b-6 positioned at a distance from the corresponding first or second row of terminals has a larger planar area and lower impedance, facilitating the flow of the electric potential or noise away from the signal terminals and into the corresponding common ground member via the contact portion 502 at the corresponding contact point. In other words, boundaries similar to the total reflection boundary are formed at the first contact point A1 and the second contact point A2 of the first ground terminal 201, as well as at the third contact point B1 and the fourth contact point B2 of the second ground terminal 301, respectively, so that the resonant frequency of the ground terminal is increased due to the shortening of the distance between the electrical boundaries, thereby changing the resonant frequency of the ground terminal.

In another embodiment not shown, the at least one common ground member includes only one common ground member, and a cross-section of the one common ground member is substantially H-shaped. The one common ground member is positioned between the first row of terminals and the second row of terminals to separate them. The substantially H-shaped common ground member has a main body portion extending in a first direction X and a plurality of contact portions extending in opposite directions from two side edges of the main body portion in a second direction Y (perpendicular to the first direction X). A cross-section of the common ground member passing through the main body portion and the contact portions is substantially H-shaped. The main body portion of the substantially H-shaped common ground member, which is located in the middle, is separated from the first row of terminals and the second row of terminals and is not in contact with the first row of terminals and the second row of terminals.

The electrical connector of the embodiment shown in FIGS. 22-25 further includes a shell 11, which can be sleeved over the outside of the housing 10 so as to be able to provide mechanical support for the mated electrical connector. In one embodiment, the shell 11 is made of metal.

The common ground member in each of the aforementioned embodiments may include a metal member or an electroplated plastic member. For example, the common ground member may be formed from metal. Alternatively, the common ground member may be formed from plastic and coated with a layer of conductive material on a surface of the common ground member formed form plastic, thereby further reducing costs.

The electrical connectors provided by the various embodiments of the present disclosure are provided with the ground shield assemblies, which separate the signal terminal of the first row of terminals from the signal terminal of the second row of terminals, so that the interference between the two rows of signal terminals is eliminated and the near-end crosstalk is improved. In addition, the ground terminals of the electrical connector can be formed with a plurality of ground contact points by contacting the ground shield assembly at a plurality of positions between the two ends of the ground terminal, and boundaries are formed by the plurality of ground contact points, which are similar to the total reflection boundary, so that the resonance frequency is increased due to the shortened distance between the electrical boundaries, thereby improving the resonance frequency of the electrical connector. That is, the resonant frequency point is increased to a higher frequency point, thereby improving the high-frequency resonance of the electrical connector. In addition, the potential or noise generated in the two rows of ground terminals can flow into the ground shield assembly or the common ground member with lower impedance, thereby improving the high-frequency resonance of the electrical connector.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. An electrical connector, comprising:
a housing;
a first row of terminals and a second row of terminals arranged in the housing and separated from each other, and adapted to be electrically connected with corresponding terminals of a mated electrical connector, the first row of terminals and the second row of terminals each including a ground terminal adapted to be connected to a ground layer of a circuit board and a signal terminal adapted to be connected to a signal lead wire of the circuit board; and
a ground shield assembly at least partially positioned between the signal terminal of the first row of terminals and the signal terminal of the second row of terminals and adapted to be electrically connected to the ground layer, the ground shield assembly in electrical contact with a corresponding ground terminal at at least one position of each of at least one ground terminal of the first row of terminals and/or the second row of terminals.

2. The electrical connector according to claim 1, wherein the ground shield assembly includes a conductive shield member positioned at least partially between the signal terminal of the first row of terminals and the signal terminal of the second row of terminals and adapted to be electrically connected to the ground layer.

3. The electrical connector according to claim 2, wherein:
the ground shield assembly further includes at least one common ground member, each common ground member in contact with the corresponding ground terminal at at least two positions of each of the at least one ground terminal of the first row of terminals and/or the second row of terminals; and
each common ground member is electrically connected with the conductive shield member.

4. The electrical connector according to claim 3, wherein:
each common ground member includes a main body portion extending in a first direction parallel to a terminal arrangement direction of the first row of terminals or the second row of terminals, and a plurality of contact portions extending from two side edges of the main body portion in a second direction perpendicular to the first direction, a cross-section of the common ground member passing through the main body portion and the contact portions is substantially U-shaped; and
two contact portions arranged opposite to each other in the second direction are in contact with a common ground terminal of the first row of terminals or a common ground terminal of the second row of terminals.

5. The electrical connector according to claim 4, wherein:
the first row of terminals includes a first ground terminal arranged between its signal terminals;
the second row of terminals includes a second ground terminal arranged between its signal terminals; and
the at least one common ground member includes:
a first common ground member arranged on an outer side of the first row of terminals away from the second row of terminals, the first common ground member in contact with a corresponding first ground terminal at two positions in an extension direction of each first ground terminal; and
a second common ground member arranged on an outer side of the second row of terminals away from the first row of terminals, the second common ground member in contact with a corresponding second ground terminal at two positions in an extension direction of each second ground terminal.

6. The electrical connector according to claim 5, wherein at least one of the first common ground member and the second common ground member has a connecting leg which extends from an end of the main body portion in the first direction to the conductive shield member so as to be in electrical contact with the conductive shield member.

7. The electrical connector according to claim 6, further comprising a first terminal fixing member and a second terminal fixing member, the first ground terminal and the first signal terminal of the first row of terminals extending through the first terminal fixing member and being fixed by the first terminal fixing member, and the second ground terminal and the second signal terminal of the second row of terminals extending through the second terminal fixing member and being fixed by the second terminal fixing member, wherein:
the first common ground member is positioned on a side of the first terminal fixing member opposite to the conductive shield member such that the first common ground member crosses the first terminal fixing member to be in electrical contact with two separated sections of each first ground terminal, and the main body portion of the first common ground member located at a base of the substantially U-shaped shape is separated from the first ground terminal by the first terminal fixing member; and
the second common ground member is positioned on a side of the second terminal fixing member opposite to the conductive shield member such that the second common ground member crosses the second terminal fixing member to be in electrical contact with two separated sections of each second ground terminal, and the main body portion of the second common ground member located at a base of the substantially U-shaped shape is separated from the second ground terminal by the second terminal fixing member.

8. The electrical connector according to claim 4, wherein:
the first row of terminals includes a first ground terminal arranged between its signal terminals;
the second row of terminals includes a second ground terminal arranged between its signal terminals; and
the at least one common ground member includes at least one of:
a first common ground member arranged on an inner side of the first row of terminals facing the second row of terminals, and in contact with the first ground terminal at two positions in an extension direction of each first ground terminal; or
a second common ground member arranged on an inner side of the second row of terminals facing the first row of terminals, and in contact with the second ground terminal at two positions in an extension direction of each second ground terminal.

9. The electrical connector according to claim 8, wherein at least one of:
a surface of the main body portion of the first common ground member facing the second row of terminals is in contact with a side surface of the conductive shield member facing the first row terminals; or
a surface of the main body portion of the second common ground member facing the first row of terminals is in contact with a side surface of the conductive shield member facing the second row of terminals.

10. The electrical connector according to claim 9, wherein:
the electrical connector further includes a first terminal fixing member and a second terminal fixing member, the first ground terminal and the first signal terminal of the first row of terminals extend through the first terminal fixing member and are fixed by the first terminal fixing member, and the second ground terminal and the second signal terminal of the second row of terminal extend through the second terminal fixing member and are fixed by the second terminal fixing member;
the first common ground member is arranged on a side of the first terminal fixing member facing the conductive shield member such that the first common ground member crosses the first terminal fixing member to be in electrical contact with two separated sections of each first ground terminal, and the main body portion of the first common ground member located at a base of the substantially U-shaped shape is separated from the first ground terminal by the first terminal fixing member;
the second common ground member is arranged on a side of the second terminal fixing member facing the conductive shield member such that the second common ground member crosses the second terminal fixing member to be in electrical contact with two separated sections of each second ground terminal; and
the main body portion of the second common ground member located at a base of the substantially U-shaped shape is separated from the second ground terminal by the second terminal fixing member.

11. The electrical connector according to claim 4, wherein:
the first row of terminals includes a first ground terminal arranged between its signal terminals;
the second row of terminals includes a second ground terminal arranged between its signal terminals;
the ground shield assembly includes one common ground member, the common ground member is in contact with one of the first ground terminal and the second ground terminal; and
the conductive shield member is in electrical contact with the other of the first ground terminal and the second ground terminal.

12. The electrical connector according to claim 11, wherein the conductive shield member is in electrical contact with the one ground terminal at at least one position such that the one ground terminal is divided into at least four sections in its extension direction by positions wherein the one ground terminal is in contact with the conductive shield member and the common ground member.

13. The electrical connector according to claim 2, wherein:
the first row of terminals includes a first ground terminal arranged between its signal terminals;
the second row of terminals includes a second ground terminal arranged between its signal terminals; and
the conductive shield member is in electrical contact with each of the first ground terminal and the second ground terminal at at least one position in an extension direction of the ground terminal such that each contacted ground terminal is divided into at least two sections in the extension direction by the position where the ground terminal is in contact with the conductive shield member.

14. The electrical connector according to claim 8, wherein:
a length of the first ground terminal is longer than that of the second ground terminal, and a gap is formed between a portion of the first ground terminal and the conductive shield member; and
the at least one common ground member further includes a third common ground member provided in the gap to directly contact each first ground terminal of the first row of terminals and the conductive shield member, respectively, such that each first ground terminal is divided into four sections in the extension direction by positions where the first ground terminal is in contact with the first common ground member and the third common ground member, the third common ground member having a body extending in a first direction parallel to a terminal arrangement direction of the first row of terminals, and a plurality of protrusions protruding from a surface of the body facing the first row of terminals and being in contact with the first ground terminal.

15. The electrical connector according to claim 2, wherein:
the conductive shield member includes a shield member body and a shield member contact portion, the shield member contact portion extending from the shield member body to be in electrical contact with the ground terminal;
the contact portion of each of the at least one common ground member is formed as a protrusion protruding from a surface of the main body portion facing the first row of terminals or the second row of terminals;
the ground shield assembly further includes a positioning member provided within the housing, and the positioning member fixedly positions the conductive shield member between the first row of terminals and the second row of terminals relative to the housing;
the conductive shield member is adapted to be directly electrically connected to the ground layer, or be indirectly electrically connected to the ground layer via the ground terminal; and
the at least one common ground member includes a metal member or an electroplated plastic member.

16. An electrical connector, comprising:
a housing;
a first row of terminals and a second row of terminals housed in the housing separated from each other and adapted to be electrically connected with corresponding terminals of a mated electrical connector, the first row of terminals and the second row of terminals each comprising a ground terminal adapted to be connected to a ground layer of a circuit board and a signal terminal adapted to be connected to a signal lead wire of the circuit board; and
at least one common ground member positioned between the signal terminal of the first row of terminals and the signal terminal of the second row of terminals, and in contact with a corresponding ground terminal at at least one position of each first ground terminal of the first row of terminals and each second ground terminal of the second row of terminals.

17. The electrical connector according to claim 16, wherein:
the first row of terminals includes a first ground terminal arranged between its signal terminals;
the second row of terminals includes a second ground terminal arranged between its signal terminals; and
the at least one common ground member includes:
a first common ground member arranged on an inner side of the first row of terminals facing the second row of terminals, and in contact with a corresponding first ground terminal at two positions in an extension direction of each first ground terminal; and
a second common ground member arranged on an inner side of the second row of terminals facing the first row of terminals, and in contact with a corresponding second ground terminal at two positions in an extension direction of each second ground terminal.

18. The electrical connector according to claim 17, wherein:
each common ground member includes a main body portion extending in a first direction parallel to a terminal arrangement direction of the first row of terminals or the second row of terminals, and a plurality of contact portions extending from two side edges of the main body portion in a second direction perpendicular to the first direction, a cross-section of the common ground member passing through the main body portion and the contact portions is in the form of a substantially C-shaped shape;
a base of the substantially C-shaped shape of the first common ground member is abutted against a base of the substantially C-shaped shape of the second common ground member; and
two contact portions arranged opposite to each other in the second direction are in contact with a common ground terminal of the first row of terminals or a common ground terminal of the second row of terminals.

19. The electrical connector according to claim 18, further comprising a first terminal fixing member and a second terminal fixing member, wherein:
the first ground terminal and the first signal terminal of the first row of terminals extend through the first terminal fixing member and are fixed by the first terminal fixing member, and the second ground terminal and the second signal terminal of the second row of terminals extend through the second terminal fixing member and are fixed by the second terminal fixing member;
the first common ground member is positioned on a side of the first terminal fixing member facing the second common ground member such that the first common ground member crosses the first terminal fixing member to be in electrical contact with two separated sections of each first ground terminal, and the main body portion of the first common ground member located at the base of the substantially C-shaped shape is separated from the first ground terminal by the first terminal fixing member; and
the second common ground member is positioned on a side of the second terminal fixing member facing the first common ground member such that the second common ground member crosses the second terminal fixing member to be in electrical contact with two separated sections of each second ground terminal, and the main body portion of the second common ground member located at the base of the substantially C-shaped shape is separated from the second ground terminal by the second terminal fixing member.

20. The electrical connector according to claim 16, wherein at least one of:
the electrical connector is a vertical electrical connector with one end adapted to be installed on the circuit board and the other end adapted to be mated with the mated electrical connector opposite to the one end; or
the electrical connector further comprises a shell sleeved over the outside of the housing.
